(19) United States
(12) Patent Application Publication
(10) Pub. No.: US 2024/0387724 A1
(43) Pub. Date: Nov. 21, 2024

(54) SILICON CARBIDE SEMICONDUCTOR DEVICE

(71) Applicant: FUJI ELECTRIC CO., LTD., Kawasaki-shi (JP)

(72) Inventor: Keiji OKUMURA, Matsumoto-city (JP)

(73) Assignee: FUJI ELECTRIC CO., LTD., Kawasaki-shi (JP)

(21) Appl. No.: 18/785,730

(22) Filed: Jul. 26, 2024

Related U.S. Application Data
(63) Continuation of application No. PCT/JP2023/023685, filed on Jun. 26, 2023.

(30) Foreign Application Priority Data
Aug. 9, 2022 (JP) 2022-127271

(51) Int. Cl. H01L 29/78; H01L 27/088; H01L 29/06; H01L 29/16; H01L 29/423

(52) U.S. Cl. CPC H01L 29/7813; H01L 27/088; H01L 29/0696; H01L 29/4236; H01L 29/7831; H01L 29/1608; H01L 29/7811

(57) ABSTRACT

A silicon carbide semiconductor device, including: a semiconductor substrate; a first semiconductor region, a second semiconductor region and a plurality of third semiconductor regions provided in the semiconductor substrate; a plurality of first trenches penetrating through the third semiconductor regions and the second semiconductor region in a depth direction and terminating in the first semiconductor region; a plurality of gate electrodes provided in the first trenches via gate insulating films; a plurality of second trenches penetrating through the third semiconductor regions in the depth direction and terminating in the second semiconductor region; and a first electrode and a second electrode provided respectively on two main surfaces of the semiconductor substrate. The second trenches are provided at a predetermined first pitch in a direction parallel to the semiconductor substrate. The first trenches are disposed at a predetermined second pitch in the direction, each between adjacent two of the second trenches.

### CROSS REFERENCE TO RELATED APPLICATIONS

This is a continuation application of International Application PCT/JP2023/023685 filed on Jun. 26, 2023 which claims priority from a Japanese Patent Application No. 2022-127271 filed on Aug. 9, 2022, the contents of which are incorporated herein by reference.

### BACKGROUND OF THE INVENTION

### 1. Field of the Invention

Embodiments of the invention relate to a silicon carbide semiconductor device.

### 2. Description of the Related Art

A double trench structure having a gate trench embedded with a gate electrode, a source trench embedded with a source electrode, and a source contact (electrical contact) in contact with the source electrode and formed along an inner wall is a conventionally known trench gate SiC-MOSFET (metal oxide semiconductor field effect transistor having a metal-oxide-semiconductor three-layer structure) that uses silicon carbide (SiC) as a semiconductor material.

The structure of a conventional silicon carbide semiconductor device is described. FIG. 9 is a cross-sectional view depicting the structure of the conventional silicon carbide semiconductor device. A conventional silicon carbide semiconductor device 110 depicted in FIG. 9 is a trench gate SiC-MOSFET with a double trench structure having a semiconductor substrate 130 containing silicon carbide, and source trenches 111 provided in the semiconductor substrate 130, at a front surface (a main surface constituted by a surface of an epitaxial layer 132) of the semiconductor substrate 130. In the semiconductor substrate 130, the epitaxial layer 132 of an n⁻-type is formed by epitaxy on an n⁺-type starting substrate 131 containing silicon carbide, the epitaxial layer 132 constituting an n⁻-type drift region 102.

The n⁺-type starting substrate 131 constitutes an n⁺-type drain region 101. In the epitaxial layer 132, a region excluding diffused regions (a p-type base region 103, n⁺-type source regions 105, and p⁺⁺-type contact regions 106) formed by ion implantation in the epitaxial layer 132 constitutes the n⁻-type drift region 102. In the semiconductor substrate 130, at the front surface thereof, a trench gate structure is configured by the p-type base region 103, the n⁺-type source regions 105, the p⁺⁺-type contact regions 106, gate trenches 107, gate insulating films 108, and gate electrodes 109.

The gate trenches 107 and the source trenches 111 are provided alternating with one another repeatedly in a first direction X parallel to the front surface of the semiconductor substrate 130. A unit cell (functional unit of a device) 116 includes one of the gate trenches 107 and a half of each of the source trenches 111 adjacent to the one of the gate trenches 107. The gate trenches 107 penetrate through the n⁺-type source regions 105 and the p-type base region 103 in a depth direction Z from the front surface of the semiconductor substrate 130 and terminate in the n⁻-type drift region 102. In the gate trenches 107, the gate electrodes 109 are provided on the gate insulating films 108.

The source trenches 111 penetrate through the n⁺-type source regions 105 in the depth direction Z from the front surface of the semiconductor substrate 130. A depth of the source trenches 111 is at least equal to a depth of the gate trenches 107. One of the unit cells 116 is configured by a portion between centers of any adjacent two of the source trenches 111 in the first direction X. In the source trenches 111, a source electrode 113 is embedded. Between the n⁻-type drift region 102 and the source trenches 111, the p-type base region 103 extends along inner walls of the source trenches 111.

Portions (hereinafter, p-type deep base portions) 104 of the p-type base region 103 along bottoms of the source trenches 111 form pn junctions with the n⁻-type drift region 102 at deep positions closer to the n⁺-type drain region 101 than are bottoms of the gate trenches 107. In the double trench structure, the p-type deep base portions 104 at the bottoms of the source trenches 111 have a function of mitigating electric field applied to the gate insulating films 108 at the bottoms of the gate trenches 107. Thus, p-type regions are not disposed at positions facing the bottoms of the gate trenches 107.

No p-type regions are disposed at positions facing the bottoms of the gate trenches 107, whereby a width of a junction FET (JFET) portion increases, thereby significantly reducing JFET resistance, whereby on-resistance is reduced. The JFET portion is a portion of the n⁻-type drift region 102 adjacent to a channel (n-type inversion layer) formed along the gate trenches 107 in the p-type base region 103 when the SiC-MOSFET is on, the portion forms a current path of a main current (drift current) that passes through the channel.

The source trenches 111 are exposed in contact holes 112a of an interlayer insulating film 112. The source electrode 113, via the contact holes 112a of the interlayer insulating film 112, is embedded in the source trenches 111 and is in contact with the p-type base region 103, the n⁺-type source regions 105, and the p⁺⁺-type contact regions 106, at inner walls of the source trenches 111. A drain electrode 114 is provided in an entire area of a back surface (main surface constituted by a surface of the n⁺-type starting substrate 131) of the semiconductor substrate 130 and is electrically connected to the n⁺-type drain region 101.

As for a conventional trench gate SiC-MOSFET, a device has been proposed that is a single trench structure having only gate trenches and in which p⁺-type regions for mitigating electric field near bottoms of the gate trench are disposed at positions facing the bottoms of all the gate trenches and are selectively provided between adjacent gate trenches (in mesa regions) (for example, refer to Japanese Patent No. 6919159 and Japanese Patent No. 5751213). In Japanese Patent No. 6919159 and Japanese Patent No. 5751213, mesa regions free of a p⁺-type region are provided, whereby an area that the trench gate structure occupies relative to the area of the active region is increased and on-resistance is lowered.

Patent Document 1: Japanese Patent No. 6919159 and Japanese Patent No. 5751213

### SUMMARY OF THE INVENTION

According to an embodiment of the present invention, a silicon carbide semiconductor device includes: a semiconductor substrate containing silicon carbide and having a first main surface and a second main surface opposite to each other; a first semiconductor region of a first conductivity type provided in the semiconductor substrate; a second semiconductor region of a second conductivity type, provided in the semiconductor substrate between the first main surface of the semiconductor substrate and the first semiconductor region; a plurality of third semiconductor regions of the first conductivity type, selectively provided in the semiconductor substrate between the first main surface of the semiconductor substrate and the second semiconductor region; a plurality of first trenches penetrating through the plurality of third semiconductor regions and the second semiconductor region in a depth direction and terminating in the first semiconductor region; a plurality of gate electrodes provided in the plurality of first trenches, via a plurality of gate insulating films; a plurality of second trenches penetrating through the plurality of third semiconductor regions in the depth direction and terminating in the second semiconductor region, at a depth at least equal to a depth of the plurality of first trenches, each of the plurality of second trenches being provided apart from the plurality of first trenches; a first electrode provided at the first main surface of the semiconductor substrate, the first electrode being embedded in the plurality of second trenches, and in contact with the second semiconductor region and the plurality of third semiconductor regions at inner walls of the plurality of second trenches; and a second electrode provided at the second main surface of the semiconductor substrate. The plurality of second trenches is provided at a predetermined first pitch in a direction parallel to the first main surface of the semiconductor substrate. The plurality of first trenches is disposed at a predetermined second pitch in the direction, each between adjacent two of the plurality of second trenches.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting a layout when a silicon carbide semiconductor device according to a first embodiment is viewed from a front side of a semiconductor substrate thereof.

FIG. 2 is a cross-sectional view depicting the structure along cutting line A-A′ in FIG. 1.

FIG. 3 is a cross-sectional view depicting the structure along cutting line B-B′ in FIG. 1.

FIG. 4 is a cross-sectional view depicting the structure along cutting line C-C′ in FIG. 1.

FIG. 5 is a cross-sectional view depicting the structure along cutting line D-D′ in FIG. 1.

FIG. 6 is a cross-sectional view depicting the structure along cutting line E-E′ in FIG. 1.

FIG. 7 is an enlarged view of a portion in a rectangular frame F in FIG. 1.

FIG. 8 is a cross-sectional view depicting a structure of a silicon carbide semiconductor device according to a second embodiment.

FIG. 9 is a cross-sectional view depicting a structure of a conventional silicon carbide semiconductor device.

### DETAILED DESCRIPTION OF THE INVENTION

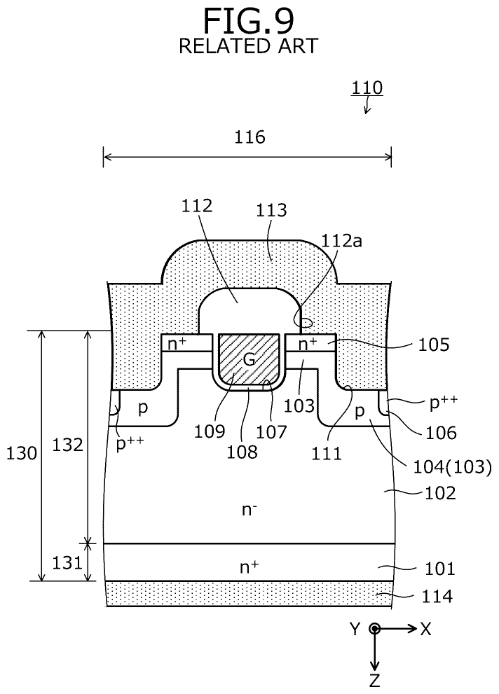

First, problems associated with the conventional techniques are discussed. In the conventional silicon carbide semiconductor device 110 (refer to FIG. 9), as for a double trench structure, p-type regions for mitigating electric field near the bottoms of the gate trenches 107 are not disposed at positions facing the bottoms of the gate trenches 107, whereby the on-resistance may be reduced, however, for the one gate trench 107 of any one of the unit cells 116, one half of a source trench 111 has to be disposed on each side of the one gate trench 107. Thus, shrinking (reducing) the cell pitch (arrangement interval of the unit cells 116) is difficult and further reduction of the on-resistance is difficult.

Embodiments of a silicon carbide semiconductor device according to the present invention are described in detain with reference to the accompanying drawings. In the present description and accompanying drawings, layers and regions prefixed with n or p mean that majority carriers are electrons or holes. Additionally, +or − appended to n or p means that the impurity concentration is higher or lower, respectively, than layers and regions without + or −. In the description of the embodiments below and the accompanying drawings, main portions that are identical are given the same reference numerals and are not repeatedly described.

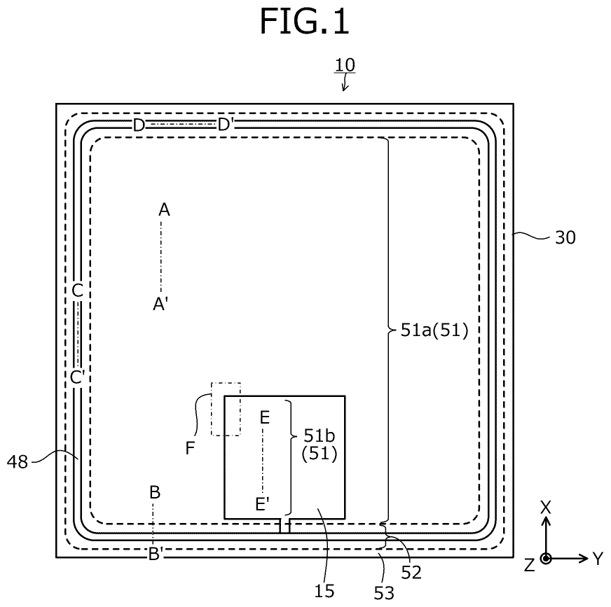

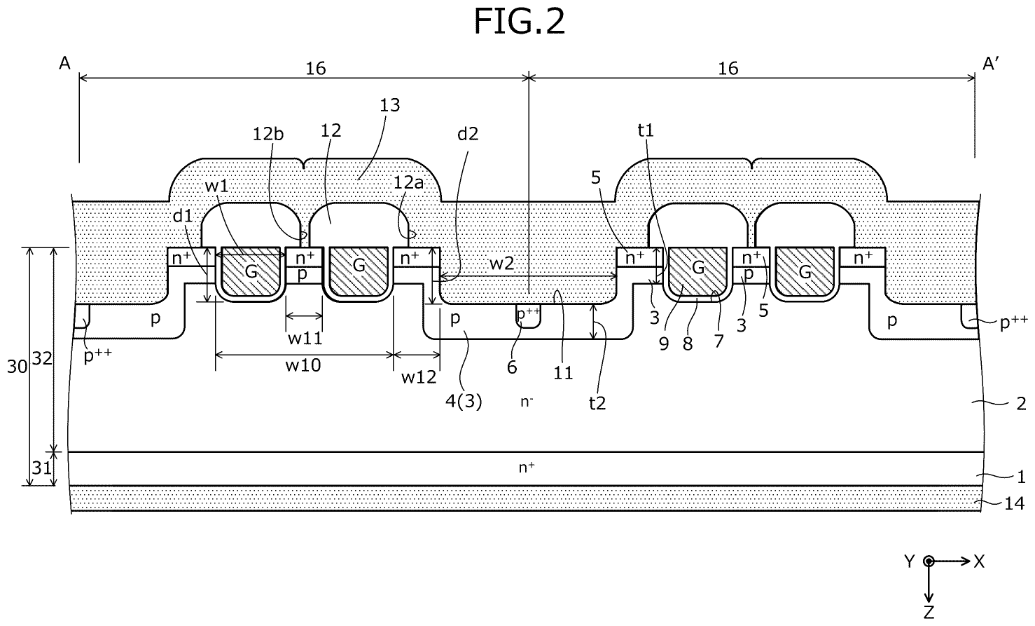

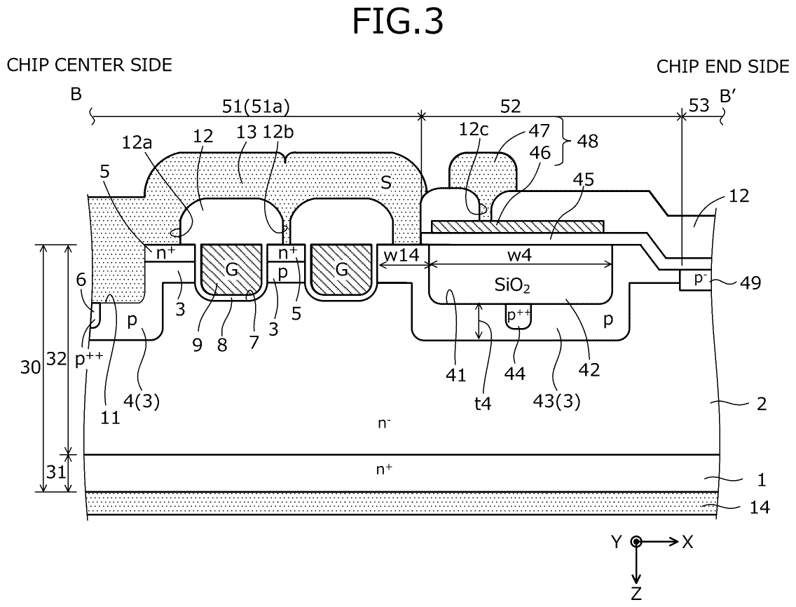

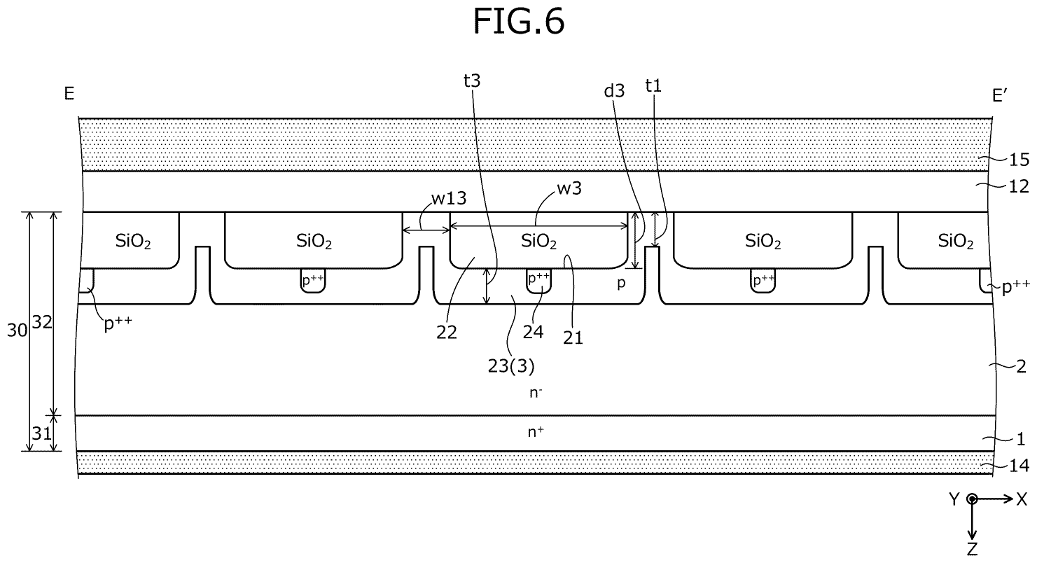

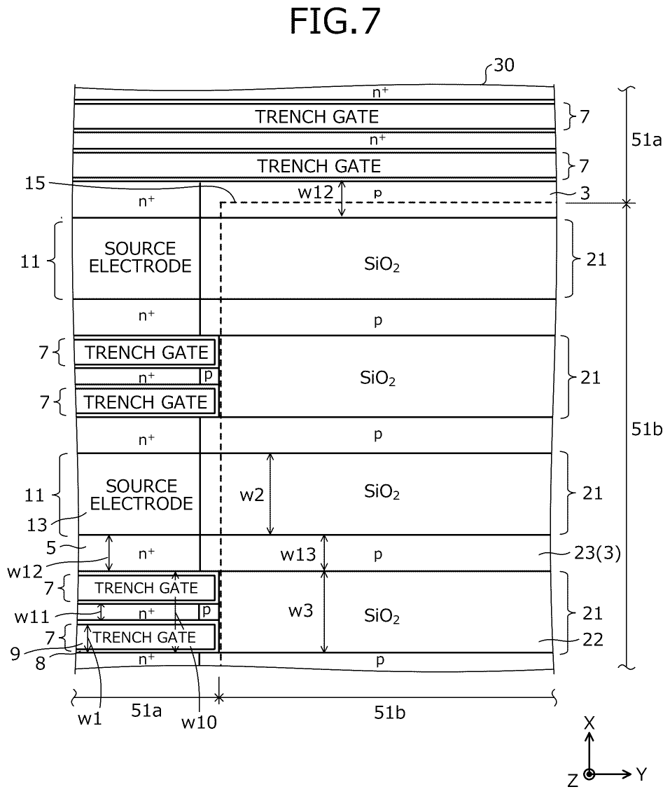

A structure of a silicon carbide semiconductor device according to a first embodiment is described. FIG. 1 is a plan view depicting a layout when the silicon carbide semiconductor device according to the first embodiment is viewed from a front side of a semiconductor substrate thereof. FIGS. 2, 3, 4, 5, and 6 are cross-sectional views, respectively, depicting the structure along cutting line A-A′, cutting line B-B′, cutting line C-C′, cutting line D-D′, and cutting line E-E′ in FIG. 1. FIG. 7 is an enlarged view of a portion in a rectangular frame F in FIG. 1. FIG. 2 depicts two adjacent unit cells 16 (functional units of a device) of an active region 51. Any one of the unit cells 16 is configured by a portion between a center of one of multiple source trenches 11 and a center of an adjacent one of the source trenches 11 in the first direction X. FIGS. 3 to 5 depict a structure of an intermediate region 52. FIG. 6 depicts a structure directly beneath a gate pad 15 (side facing an n⁺-type drain region 1).

FIG. 7 depicts a layout the source trenches 11 and gate trenches 7 in a vicinity of a border between the source electrode 13 and the gate pad 15. In FIG. 7, while a vicinity of one corner (vertex of a rectangle) of the gate pad 15 is depicted, a layout of the gate trenches 7 and the source trenches 11 of portions along an outer periphery of the gate pad 15 is a layout corresponding to the source trenches 11 and the gate trenches 7 of the source electrode 13. In FIG. 7, gate electrodes 9 are indicated as “trench gate” and the source electrode 13 embedded in the source trenches 11 is indicated as “source electrode”. In FIGS. 3, 4, 6, and 7, embedded insulating layers 22, 42 embedded in insulating trenches 21, 41 is indicated as “SiO₂”.

A silicon carbide semiconductor device 10 according to the present embodiment depicted in FIGS. 1 to 7 is a trench gate SiC-MOSFET with a multi-trench structure having, in the active region 51, two or more of the gate trenches (first trenches) 7 for every one of the source trenches (second trenches) 11 in the front side of the semiconductor substrate (semiconductor chip) 30 containing silicon carbide. The active region 51 is a region through which a main current (drift current) passes in a direction orthogonal to a front surface of a semiconductor substrate 30 when the silicon carbide semiconductor device 10 is on. In the active region 51, the unit cells 16 each having the same SiC-MOSFET structure are provided adjacent to one another. The active region 51, for example, has a substantially rectangular shape in a plan view and is provided in substantially a center (chip center) of the semiconductor substrate 30.

In the active region 51, on the front surface of the semiconductor substrate 30, the source electrode 13 (first electrode, not depicted in FIG. 1, refer to FIGS. 2, 3) and the gate pad 15 are provided. The source electrode 13 covers nearly an entire area of the front surface of the semiconductor substrate 30, in the active region 51. The source electrode 13, for example, has a substantially rectangular shape in which a portion is recessed inward (direction toward the chip center) in a plan view. The source electrode 13 also serves as a source pad (electrode pad). The gate pad 15, for example, has a substantially rectangular shape in a plan view (not depicted). The gate pad 15, for example, is provided near a border between the active region 51 and the intermediate region 52, the gate pad being provided in the recessed portion of the source electrode 13 so that three sides of the gate pad 15 face the source electrode 13.

An edge termination region 53 is a region between the active region 51 and an end (chip end) of the semiconductor substrate 30; the edge termination region 53 surrounds a periphery of the active region 51 in a substantially rectangular shape with the intermediate region 52 intervening therebetween. In FIG. 1, the border between the active region 51 and the intermediate region 52, and a border between the intermediate region 52 and the edge termination region 53 are indicated by dashed lines. In the intermediate region 52, which is between the active region 51 and the edge termination region 53, a gate runner 48 is provided. The intermediate region 52 is a transition region in which a structure for electrically connecting the trench gate structure of the active region 51 and a voltage withstanding structure of the edge termination region 53 is disposed. The gate runner 48 surrounds the periphery of the active region 51 in a substantially rectangular shape. The gate runner 48 is connected to the gate pad 15.

The edge termination region 53 has a function of mitigating electric field of a front side of the semiconductor substrate 30 and sustaining a breakdown voltage. The breakdown voltage is a maximum voltage at which no damage or malfunction occurs in the silicon carbide semiconductor device 10 (SiC-MOSFET) at an operating voltage. In the edge termination region 53, for example, a general voltage withstanding structure (not depicted) configured by multiple p-type regions surrounding the periphery of the active region 51 in concentric shapes, such as a field limiting ring (FLR), a junction termination extension (JTE), or a guard ring is disposed. For example, in FIG. 3, in a JTE structure in which multiple p-type regions are disposed in descending order of dopant concentration in a direction from the chip center to the chip end, a p⁻-type region 49 that is innermost among the p-type regions is depicted.

The semiconductor substrate 30 is formed by growing, by epitaxy on a front surface of an n⁺-type starting substrate 31 containing silicon carbide, an epitaxial layer 32 of an n⁻-type, the epitaxial layer 32 constituting an n⁻-type drift region (first semiconductor region) 2. The semiconductor substrate 30 has a first main surface having the epitaxial layer 32 as a front surface and a second main surface having the n⁺-type starting substrate 31 as a back surface. The n⁺-type starting substrate 31 constitutes the n⁺-type drain region 1. A portion of the epitaxial layer 32 excluding the p-type base region (second semiconductor region) 3, n⁺-type source regions (third semiconductor regions) 5, and p⁺⁺-type contact regions 6 constitutes the n⁻-type drift region 2. The trench gate structure is configured by the p-type base region 3, the n⁺-type source regions 5, the p⁺⁺-type contact regions 6, the gate trenches 7, gate insulating films 8, and the gate electrodes 9 at the front side of the semiconductor substrate 30.

The p-type base region 3, the n⁺-type source regions 5, and the p⁺⁺-type contact regions 6 are diffused regions formed by ion implantation in the epitaxial layer 32. The p-type base region 3 is provided between the front surface of the semiconductor substrate 30 and the n⁻-type drift region 2, in the entire area of the active region 51 and the intermediate region 52. The n⁺-type source regions 5 are provided between the front surface of the semiconductor substrate 30 and the p-type base region 3, in substantially an entire area of a region (first region) 51a directly beneath the source electrode 13, the n⁺-type source regions 5 being in contact with the p-type base region 3. The region 51a directly beneath the source electrode 13 is a portion of the active region 51, excluding a region (second region)) 51b of the active region 51, directly beneath the gate pad 15. The n⁺-type source regions 5 are in ohmic contact with the source electrode 13 at the front surface of the semiconductor substrate 30.

The p⁺⁺-type contact regions 6 are provided between bottoms of the source trenches 11 and later-described p-type deep base portions 4, the p⁺⁺-type contact regions 6 being in contact with the p-type deep base portions 4. The p⁺⁺-type contact regions 6 are in ohmic contact with the source electrode 13 at the bottoms of the source trenches 11. Between the front surface of the semiconductor substrate 30 and the p-type base region 3 is free of the p⁺⁺-type contact regions 6, whereby even when the cell pitch is narrow, formation of the trench gate structure is easy. The p⁺⁺-type contact regions 6 may be provided at a part of the bottoms of the source trenches 11 or may be provided in an entire area of the bottoms of the source trenches 11. The p⁺⁺-type contact regions 6 may penetrate through the p-type deep base portions 4 in the depth direction Z to be in contact with the n⁻-type drift region 2. The p⁺⁺-type contact regions 6 may be omitted.

Each of the unit cells 16 is configured by two or more (in FIGS. 2 to 7, “2”) of the gate trenches 7 and an equivalent of one of the source trenches 11. In particular, for every two or more of the gate trenches 7 apart from one another in the first direction X parallel to the front surface of the semiconductor substrate 30, one of the source trenches 11 is disposed, whereby two or more of the gate trenches 7 and one of the source trenches 11 are disposed repeatedly alternating with each other in the first direction X. In other words, between any two of the source trenches 11 disposed at a predetermined pitch in the first direction X, two or more of the gate trenches 7 are disposed at a predetermined pitch in the first direction X, apart from the adjacent two of the source trenches 11. At the source of the semiconductor substrate 30, a total number of the gate trenches 7 is greater than a total number of the source trenches 11.

By increasing the number of the gate trenches 7 per unit cell, the number of channels (n-type inversion layers) formed along the gate trenches 7 by the p-type base region 3 per one unit cell when the silicon carbide semiconductor device 10 is on may be increased. Thus, as compared to the conventional structure (refer to FIG. 9), which has only one of the gate trenches 107 in each one of the unit cells 116, current density of the drift current passing through the channels is increased and the on-resistance is decreased. On the other hand, as the number of the gate trenches 7 per unit cell increases, the effect of mitigating electric field near the bottoms of the gate trenches 7 by the later-described p-type deep base portions 4 at the bottoms of the source trenches 11 decreases. Thus, preferably, the number of the gate trenches 7 per unit cell may be about three, at maximum.

In addition, the number of the gate trenches 7 per unit cell is increased, thereby making a total area (surface area) of the gate trenches 7 greater than a total area of the source trenches 11, whereby the on-resistance is further reduced. The total area of the gate trenches 7, for example, may be more than ½ times the area of the active region 51. An interval w11 between any adjacent two of the gate trenches 7 (mesa region) is substantially the same between all adjacent trenches of the gate trenches 7. The gate trenches 7 adjacent to one another in the first direction X have the same layout pattern, whereby the interval w11 between any adjacent two of the gate trenches 7 is smaller than an interval w12 between any one of the source trenches 11 and an adjacent one of the gate trenches 7 (mesa region), thereby facilitating reductions in the cell pitch.

Further, in the conventional structure, only one of the gate trenches 107 is disposed in one of the unit cells 116 and thus, when the number of the gate trenches 107 is increased by one, the number of the source trenches 111 also increases by one. Thus, in an instance of two of the gate trenches 107, for each of the gate trenches 107, a corresponding one of the unit cells 116 is configured and thus, a total of two of the unit cells 116 are disposed. On the other hand, as described above, in the first embodiment, even when the number of the gate trenches 7 is increased by one, it is possible to configure a single one of the unit cells 16 without increasing the number of the source trenches 11, whereby two of the gate trenches 7 may be disposed occupying an area having a width (dimension in the first direction X) that is less than a width of two of the unit cells 116 of the conventional structure. Thus, as compared to the conventional structure, the total area of the gate trenches 7 with respect to the area of the active region may be increased.

Further, the interval w12 between any one of the source trenches 11 and an adjacent one of the gate trenches 7 is made larger than the interval w11 between an adjacent two of the gate trenches 7, whereby a margin of formation regions of the source trenches 11 may be increased. For example, when a depth (depth from the front surface of the semiconductor substrate 30) d2 of each of the source trenches 11 is to be deeper than a depth d1 of each of the gate trenches 7, the source trenches 11 are formed by an etching process different from an etching process for the gate trenches 7, which is useful. The deeper is the depth d2 of the source trenches 11, the more easily etching progresses in a direction parallel to the front surface of the semiconductor substrate 30. Thus, preferably, the margin of the formation regions of the source trenches 11 may be set wide.

Of any two or more of the gate trenches 7 disposed between any adjacent two of the source trenches 11, the gate trenches 7 adjacent to the source trenches 11 each has an outer wall facing the adjacent source trench 11 and an interval (hereinafter, “interval between the outer walls of the adjacent gate trenches 7”) w10 between the respective outer walls may be substantially a same as a width w2 of each of the source trenches 11 in the first direction X. In this instance, a layout pattern of later-described insulating trenches (second trenches) 21, 41 may be striped patterns with respective intervals w13, w14 that are substantially a same as the interval w12 between one of the gate trenches 7 and an adjacent one of the source trenches 11. Thus, mask patterns for forming the source trenches 11 and the insulating trenches 21, 41 may be uniform.

It is favorable for a width w1 of each of the gate trenches 7 in the first direction X to be smaller than the width w2 of the source trenches 11 in the first direction X. In particular, it is favorable for the width w1 of the gate trenches 7 in the first direction X to be, for example, less than about ½ times the width w2 of the source trenches 11 in the first direction X. As a result, an effect (increased current density of the drift current) obtained by disposing two or more of the gate trenches 7 per unit cell may be enhanced. The width w1 of the gate trenches 7 in the first direction X and the width w2 of the source trenches 11 in the first direction X may be substantially the same. Substantially the same width and substantially the same interval mean, respectively, the same width and the same interval within a range that includes an allowable error due to manufacturing process variation.

The gate trenches 7 penetrate through the n⁺-type source regions 5 and the p-type base region 3 in the depth direction Z from the front surface of the semiconductor substrate 30 and terminate in the n⁻-type drift region 2. Between the n⁺-type drain region 1 and the bottoms of the gate trenches 7, only the n⁻-type drift region 2 is disposed, and the bottoms of the gate trenches 7 are formed in the n⁻-type drift region 2. Thus, compared to an instance in which p-type regions for mitigating electric field are disposed at the bottoms of the gate trenches 7, the width of the JFET portion increases and JFET resistance is significantly reduced. The JFET portion is a portion of the n⁻-type drift region 2 adjacent to a channel and forms a current path of the drift current. In the gate trenches 7, the gate electrodes 9 containing, for example, a polysilicon (poly-Si) are provided on the gate insulating films 8.

The gate trenches 7 and the source trenches 11 each extends linearly (i.e., in a stripe-shape in the entire area of the active region 51) in a second direction Y, which is parallel to the front surface of the semiconductor substrate 30 and orthogonal to the first direction X. Two or more of the gate trenches 7 may be disposed repeatedly alternating with one of the source trenches 11 in the first direction X, and two or more of the gate trenches 7 may be disposed repeatedly alternating with one of the source trenches 11 in the second direction Y. In this instance, the gate trenches 7 and the source trenches 11 have substantially rectangular shapes and appear scattered in a plan view (i.e., scattered in a matrix-like pattern in the entire area of the active region 51); the unit cells 16 are disposed adjacently in the first direction X and the unit cells 16 are disposed adjacently in the second direction Y.

The source trenches 11 penetrate through the n⁺-type source regions 5 in the depth direction Z from the front surface of the semiconductor substrate 30 and terminate at positions of a depth substantially a same as a depth of the bottoms of the gate trenches 7 or terminate at deep positions closer to the n⁺-type drain region 1 than are the bottoms of the gate trenches 7. Substantially the same depth means the same depth within a range including an allowable error (for example, within ±10%, preferably, within ±5%) due to manufacturing process variation. When the depth d2 of the source trenches 11 is substantially a same as the depth d1 of the gate trenches 7, the width w2 of the source trenches 11 in the first direction X is made substantially a same as the width w1 of the gate trenches 7 in the first direction X, whereby the source trenches 11 may be formed concurrently with the gate trenches 7 and thus, manufacturing processes may be simplified.

On the other hand, the greater is the depth d2 of the source trenches 11 as compared to the depth d1 of the gate trenches 7, the deeper the later-described p-type deep base portions 4 at the bottoms of the source trenches 11 may be formed (the closer the p-type deep base portions 4 may be formed to the n⁺-type drain region 1). The deeper are the p-type deep base portions 4 at the bottoms of the source trenches 11, the greater is the effect of mitigating electric field near the bottoms of the gate trenches 7 by the p-type deep base portions 4. Further, the p-type deep base portions 4 constitute resistance components when a large current (short-circuit current) exceeding a rated-current flows between a drain and source of the SiC-MOSFET (the silicon carbide semiconductor device 10) during load short-circuit or alarm short-circuit and thus the deeper are the p-type deep base portions 4 at the bottoms of the source trenches 11, the greater the short-circuit capability is enhanced.

The source electrode 13 is embedded in the source trenches 11. Between the n⁻-type drift region 2 and the source trenches 11, the p-type base region 3 extends along inner walls of the source trenches 11. Along the inner walls of the source trenches 11, source contacts (electrical contacts) are formed between the source electrode and the p-type base region 3 and between the source electrode and the p⁺⁺-type contact regions 6. Even when the depth d2 of the source trenches 11 is greater than the depth d1 of the gate trenches 7, the interval w12 between any one of the source trenches 11 and an adjacent one of the gate trenches 7 is suitably set, whereby gate characteristics are not adversely affected. Further, even when the source electrode 13 embedded in the source trenches 11 is positioned closer to the n⁺-type drain region 1 than are the gate electrodes 9 embedded in the gate trenches 7, the gate characteristics are not adversely affected.

Further, in the p-type base region 3, portions thereof (hereinafter, the p-type deep base portions 4) along the bottoms of the source trenches 11 border the entire area of the bottoms of the source trenches 11. The p-type deep base portions 4 at the bottoms of the source trenches 11 form pn junctions with the n⁻-type drift region 2 at deep positions closer to the n⁺-type drain region 1 than are the bottoms of the gate trenches 7, and electric field applied to the gate insulating films 8 at the bottoms of the gate trenches 7 is mitigated. Further, the source trenches 11 are provided, ion implantation of a p-type dopant for forming the p-type base region 3 at the bottoms of the source trenches 11 is performed, whereby the p-type deep base portions 4 may be formed at deep positions closer to the n⁺-type drain region 1 than are the bottoms of the gate trenches 7, without variation of doping concentration.

For example, in an instance in which the source trenches 11 are not provided between the gate trenches 7 that are adjacent to each other, to form p-type regions at deep positions toward the n⁺-type drain region 1, ion implantation of a p-type dopant has to be performed by a high acceleration energy from the front surface of the semiconductor substrate 30 or the epitaxial layer 32 has to be formed by multi-stage epitaxial growth and ion implantation of a p-type dopant has to be performed at each stage. Thus, a problem arises in that the doping concentration of the p-type regions varies due to the ion implantation by a high acceleration energy and crystal defects occur. Further, when the epitaxial layer 32 is grown in multiple stages and the ion implantation of a p-type dopant is performed at each stage, the number of processes increases.

In the present embodiment, in the semiconductor substrate 30, at the front surface thereof, the source trenches 11 are formed and thereafter, in an entire area of the front surface of the semiconductor substrate 30 in the active region 51 and in the intermediate region 52 and in an entire area of the surfaces of the inner walls of the source trenches 11, ion-implantation of a p-type dopant forming the p-type base region 3 is performed. As a result, in surface regions of the semiconductor substrate 30, at the front surface thereof in the active region 51 and the intermediate region 52 and in surface regions of the source trenches 11, at the entire surface of the inner walls of the source trenches 11, the p-type base region 3 is formed; and portions of the p-type base region 3, along the bottoms of the source trenches 11 become the p-type deep base portions 4. Thus, processes of ion implantation by a high acceleration energy and multi-stage epitaxial growth of the epitaxial layer 32 are unnecessary.

A thickness (thickness of a portion of the p-type base region 3, between the n⁻-type drift region 2 and the bottom of any one of the source trenches 11) t2 of each of the p-type deep base portions 4 may be greater than a thickness t1 of a portion of the p-type base region 3 in a mesa region (portion of the p-type base region 3, between the front surface of the semiconductor substrate 30 and the n⁻-type drift region 2). In the p-type base region 3, to make the thickness t2 of the p-type deep base portions 4 relatively thicker, a p-type dopant may be further ion-implanted at the bottoms of the source trenches 11 during formation of the p-type base region 3. For example, in the p-type base region 3, the thickness t2 of the p-type deep base portions 4 may also be made relatively thicker by performing the ion implantation of a p-type dopant for forming the p⁺⁺-type contact regions 6 at the bottoms of the source trenches 11.

In the active region 51, the trenches (hereinafter, insulating trenches) 21 in which the embedded insulating layer 22 is embedded are provided in a region 51b directly beneath the gate pad 15. Between the n⁻-type drift region 2 and the insulating trenches 21, the p-type base region 3 extends along inner walls of the insulating trenches 21 from the active region 51 and borders bottoms of the insulating trenches 21. The insulating trenches 21 each extends in a stripe-shape in the second direction Y. A width w3 of each of the insulating trenches 21 in the first direction X, preferably, for example, is substantially a same as the width w2 of each of the source trenches 11 in the first direction X. The interval w13 between any adjacent two of the insulating trenches 21, preferably, for example, is substantially a same as the interval w12 between any one of the source trenches 11 and an adjacent one of the gate trenches 7.

The insulating trenches 21 are each disposed in a stripe-shape with the dimensions above and in the region 51a directly beneath the source electrode 13, the interval w10 between the outer walls of the adjacent gate trenches 7 is substantially a same as the interval w12 between any one of the source trenches 11 and an adjacent one of the gate trenches 7. As a result, the insulating trenches 21 are each disposed in a stripe-shape and alternately face, repeatedly, in the second direction Y, any one of the source trenches 11 and all the gate trenches 7 between any adjacent two of the source trenches 11 (refer to FIG. 7). A portion of the p-type base region 3 between any adjacent two of the insulating trenches 21 and a portion the p-type base region 3 between one of the gate trenches 7 and an adjacent one of the source trenches 11 extend linearly in the second direction Y, are continuous with one another, and have the widths w12, w13 that are substantially a same.

A portion of the p-type base region 3 directly beneath the gate pad 15 has a function of suppressing rises of the potential of the region 51b directly beneath the gate pad 15 due to a steep rise of the voltage applied to a drain electrode 14. The insulating trenches 21 are disposed in the region 51b directly beneath the gate pad 15, whereby portions (hereinafter, p-type deep base portions) 23 of the p-type base region 3, along the bottoms of the insulating trenches 21, are formed at deep positions toward the n⁺-type drain region 1. A thickness t3 of each of the p-type deep base portions 23, for example, is substantially a same as the thickness t2 of the p-type deep base portions 4 at the bottoms of the source trenches 11. A depth d3 of each of the insulating trenches 21 is substantially a same as the depth d2 of the source trenches 11, whereby the p-type deep base portions 23 may be formed at positions of a depth that is substantially a same as the depth of the p-type deep base portions 4.

The p-type deep base portions 23 at the bottoms of the insulating trenches 21 that are adjacent to each other are continuous, whereby in an entire area of the region 51b directly beneath the gate pad 15, a lower surface (surface facing the n⁺-type drain region 1) of the p-type base region 3 may be substantially flat. The region 51b directly beneath the gate pad 15 is a region facing an entire area of the surface of the gate pad 15 and, in a plan view, has a substantially rectangular shape with dimensions substantially a same as the dimensions of the gate pad 15 or dimensions slightly larger than the dimensions of the gate pad 15. Between the bottoms of the insulating trenches 21 and the p-type deep base portions 23, p⁺⁺-type contact regions 24 may be provided in contact with the p-type deep base portions 23, similar to the p⁺⁺-type contact regions 6 at the bottoms of the source trenches 11.

An interlayer insulating film 12 is provided in an entire area of the front surface of the semiconductor substrate 30 and covers the gate electrodes 9. Multiple contact holes 12a, 12b, 12c penetrating through the interlayer insulating film 12 in the depth direction Z are provided. In the contact holes 12a, the source trenches 11 are exposed. In each of the contact holes 12b, a corresponding one of the n⁺-type source regions 5 between an adjacent two of the gate trenches 7 is exposed. In the contact hole 12c, a later-described gate polysilicon wiring layer 46 of the intermediate region 52 is exposed. The source electrode 13 is embedded in the source trenches 11 via the contact holes 12a of the interlayer insulating film 12 and is in contact with the p-type base region 3, the n⁺-type source regions 5, and the p⁺⁺-type contact regions 6, at the inner walls of the source trenches 11.

On a portion of the interlayer insulating film 12 in the active region 51, the gate pad 15 is provided. The source electrode 13 and the gate pad 15 are metal electrode layers provided at a same level and are electrically insulated from each other by the interlayer insulating film 12. The gate pad 15 faces the insulating trenches 21, the embedded insulating layer 22, and the p-type deep base portions 23 with the interlayer insulating film 12 therebetween. All the gate electrodes 9 are electrically connected to the gate pad 15 via the gate runner 48. The drain electrode (second electrode) 14 is provided in an entire area of the back surface (back surface of the n⁺-type starting substrate 31) of the semiconductor substrate 30. The drain electrode 14 is in ohmic contact with the back surface of the semiconductor substrate 30 and is electrically connected to the n⁺-type drain region 1 (the n⁺-type starting substrate 31).

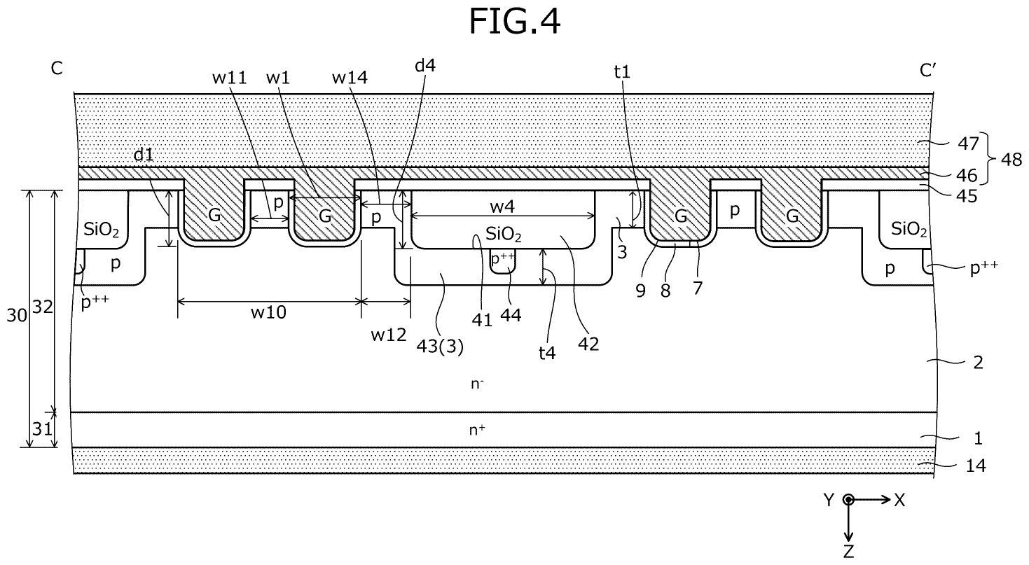

In the intermediate region 52, the gate trenches 7 extending therein from the active region 51 and the insulating trenches 41 in which the embedded insulating layer 42 is embedded are provided. Between the n⁻-type drift region 2 and the insulating trenches 41, the p-type base region 3 extends along inner walls of the insulating trenches 41 from the active region 51 and borders bottoms of the insulating trenches 41. A width w4 of each of the insulating trenches 41 in the first direction X, for example, is a same as the width w2 of the source trenches 11 in the first direction X. The intermediate region 52 surrounds the periphery of the active region 51 in substantially a rectangular shape, and at opposite sides of the intermediate region (the sides parallel to the first direction X), the insulating trenches 41 are provided facing the source trenches 11 in the second direction Y and are dispersed so that two or more of the gate trenches 7 are between any adjacent two of the source trenches 11 in the first direction X (FIG. 4).

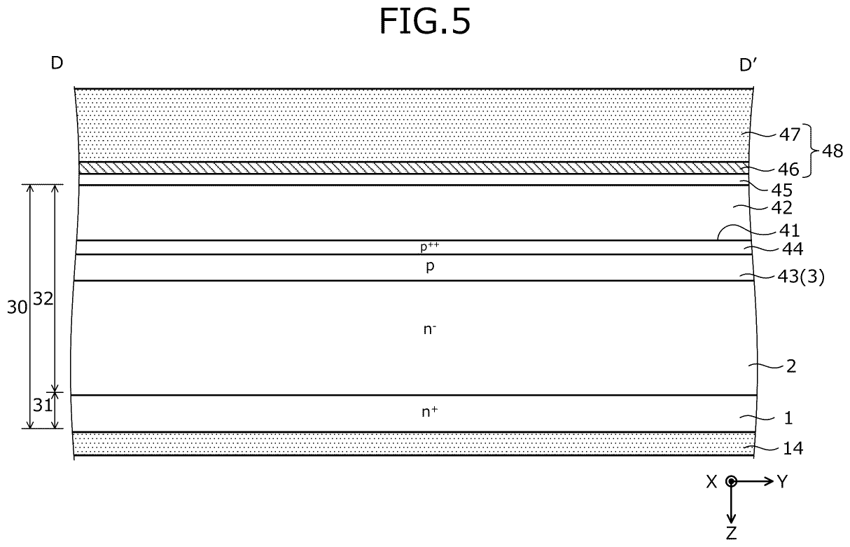

On the other hand, at opposite sides of the intermediate region 52 (the sides parallel to the second direction Y), each of the insulating trenches 41 extends linearly (or in a stripe-shape) in the second direction Y, spanning an entire area of the opposite sides (FIG. 5). In this instance, at the opposite sides of the intermediate region 52, parallel to the second direction Y, an entire area of each of the insulating trenches 41 faces, in the depth direction Z, opposite sides of the gate runner 48 (the sides parallel to the second direction Y). When the gate trenches 7 and the source trenches 11 have substantially rectangular shapes and appear scattered in a plan view (i.e., scattered in a matrix-like pattern), the insulating trenches 41 may be dispersed at the opposite sides of the intermediate region 52 (the sides parallel to the second direction Y), so that two or more of the gate trenches 7 are between any two of the insulating trenches 41 in the second direction Y (not depicted).

The insulating trenches 41 are disposed in the intermediate region 52, whereby portions (hereinafter, p-type deep base portions) 43 of the p-type base region 3 along the bottoms of the insulating trenches 41 are formed at deep positions toward the n⁺-type drain region 1. A thickness t4 of each of the p-type deep base portions 43, for example, is substantially a same as the thickness t2 of the p-type deep base portions 4 at the bottoms of the source trenches 11. A depth d4 of each of the insulating trenches 41 is substantially a same as the depth d2 of the source trenches 11, whereby the p-type deep base portions 43 may be formed at positions of a depth substantially a same as the depth of the p-type deep base portions 4. Between the bottoms of the insulating trenches 41 and the p-type deep base portions 43, p⁺⁺-type contact regions 44 may be provided in contact with the p-type deep base portions 43, similar to the p⁺⁺-type contact regions 6 at the bottoms of the source trenches 11.

In the intermediate region 52, the p-type base region 3 surrounds the periphery of the active region 51 in a substantially rectangular shape, along the border between the active region 51 and the intermediate region 52. A portion of the p-type base region 3 in the intermediate region 52 has a function of making electric field of the front surface of the semiconductor substrate 30 in the intermediate region 52 uniform. In the intermediate region 52 and the edge termination region 53, a field oxide film 45 is provided between the front surface of the semiconductor substrate 30 and the interlayer insulating film 12. The field oxide film 45 may extend between the interlayer insulating film 12 and the front surface of the semiconductor substrate 30 in the active region 51 so as to face the entire surface of the gate pad 15. The embedded insulating layers 22, 42 may be formed concurrently with the field oxide film 45.

In the intermediate region 52, the gate polysilicon wiring layer 46 is provided between the field oxide film 45 and the interlayer insulating film 12. The gate electrodes 9 are connected to the gate polysilicon wiring layer 46 at longitudinal ends (ends in the second direction Y) of the gate trenches 7. On the gate polysilicon wiring layer 46, a gate metal wiring layer 47 is provided via the contact hole 12c of the interlayer insulating film 12. The gate metal wiring layer 47 is connected to the gate pad 15. The gate polysilicon wiring layer 46 and the gate metal wiring layer 47 surround the periphery of the active region 51 and configure the gate runner 48. The gate runner 48 faces the p-type base region 3, the p-type deep base portions 43, the insulating trenches 41, and the embedded insulating layer 42, via an insulating layer (the field oxide film 45 and the interlayer insulating film 12).

Operation of the silicon carbide semiconductor device 10 (SiC-MOSFET) according to the first embodiment is described. During normal operation, voltage that is positive with respect to the source electrode 13 is applied to the drain electrode 14 (forward bias between the drain and source), whereby pn junctions between the p⁺⁺-type contact regions 6, the p-type base region 3, the n⁻-type drift region 2, and the n⁺-type drain region 1 are reverse biased. In this state, when voltage applied to the gate electrodes 9 is less than a gate threshold voltage, the SiC-MOSFET maintains an off-state.

On the other hand, when voltage that is positive with respect to the source electrode 13 is applied to the drain electrode 14 and voltage at least equal to the gate threshold voltage is applied to the gate electrodes 9, channels (n-type inversion layers) are formed in portions of the p-type base region 3 along the sidewalls of the gate trenches 7. As a result, main current (drift current) flows from the n⁺-type drain region 1, through the n⁻-type drift region 2 and the channels, toward the n⁺-type source regions 5, and the SiC-MOSFET turns on.

In the conventional structure having only one of the gate trenches 107 per one of the unit cells 116 (refer to FIG. 9), two channels are formed per unit cell. On the other hand, in the first embodiment, two or more of the gate trenches 7 are disposed in each of the unit cells 16, whereby four or more channels are formed per unit cell. As a result, as compared to the conventional structure, the current density of the drift current may be increased and thus, the on-resistance may be reduced.

As described above, according to the first embodiment, two or more of the gate trenches are disposed between any adjacent two of the source trenches, whereby the number of gate trenches per unit cell increases and thus, the number of channels per unit cell may be increased. Thus, as compared to the conventional structure having only one gate trench per unit cell (refer to FIG. 9), the current density of the drift current passing through the channels increases and the on-resistance is reduced.

Further, two or more of the gate trenches are disposed between any adjacent two of the source trenches, whereby the number of gate trenches may be increased without increasing the number of source trenches, which constitute non-operating regions that are do not function as the MOSFET. In an area equivalent to less than two unit cells of the conventional structure, two gate trenches may be disposed and as compared to the conventional structure, the total area of the gate trenches with respect to the area of the active region may be increased and thus, the on-resistance is reduced.

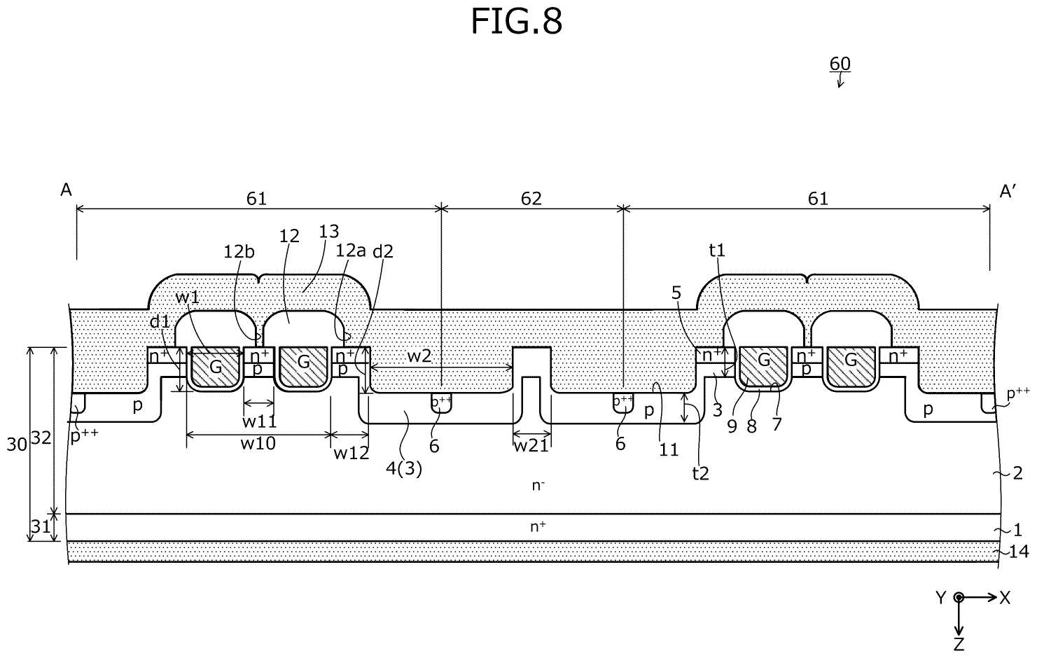

A structure of a silicon carbide semiconductor device according to a second embodiment is described. FIG. 8 is a cross-sectional view depicting the structure of the silicon carbide semiconductor device according to the second embodiment. A layout of a silicon carbide semiconductor device 60 according to the second embodiment when viewed from the front side of the semiconductor substrate 30 is a same as the layout of the first embodiment (refer to FIG. 1). The silicon carbide semiconductor device 60 according to the second embodiment differs from the silicon carbide semiconductor device 10 according to the first embodiment (refer to FIGS. 1 to 7) in that an adjacent two of the source trenches 11 sandwiching the gate trenches 7 therebetween and an adjacent two of the source trenches 11 not sandwiching the gate trenches 7 therebetween are provided repeatedly alternating with one another in the first direction X.

In particular, in the second embodiment, a set of two or more (in FIG. 8, “2”) of the gate trenches 7 and a set of two of the source trenches 11 are disposed repeatedly alternating with one another in the first direction X, whereby multiple unit cells 61 are disposed apart from one another in the first direction X. Similar to the first embodiment, any one of the unit cells 61 is configured by a portion between a center of one of source trenches 11 and a center of an adjacent one of the source trenches 11 in the first direction X; two or more of the gate trenches 7 intervene between the one and adjacent one of the source trenches 11. Between any adjacent two of the unit cells 61 is a non-operating region 62 that does not function as the MOSFET, the non-operating region 62 being between a center of one of the source trenches 11 and a center of an adjacent one of the source trenches 11 in the first direction X; only the p-type base region 3 intervenes between the one and adjacent one of the source trenches 11.

In each of the non-operating regions 62, an area between the source trenches 11 adjacent to each other (mesa region) is free of the gate trenches 7 and the n⁺-type source regions 5, only the p-type base region 3 is disposed. The source electrode 13 and the p-type base region 3 are in contact with each other at substantially the entire surface of the inner walls of the source trenches 11 and thus, as compared to an instance in which one of the source trenches 11 of a width that is a same as a total width (=2×w2) of an adjacent two of the source trenches in the first direction is provided instead of an adjacent two of the source trenches 11 disposed in one of the non-operating regions 62, the area of contact between the source electrode 13 and the p-type base region 3 increases. Thus, avalanche capability may be enhanced.

Further, the area of parasitic diodes (body diodes) formed by pn junctions between the p⁺⁺-type contact regions 6, the p-type base region 3, the n⁻-type drift region 2, and the n⁺-type drain region 1 increases by an amount equivalent to the increased area of contact between the source electrode 13 and the p-type base region 3. Thus, forward voltage Vf of the body diodes may be reduced. Further, the non-operating region 62 is provided, whereby the width of the contact holes 12a exposing the source trenches 11 increases and thus, embedding of the source electrode 13 in the source trenches 11 is facilitated and an occurrence of voids (porous state) in the source electrode 13 is inhibited. Thus, a plating film formed on the source electrode 13 for wire bonding is inhibited from infiltrating toward the semiconductor substrate 30.

Further, embeddability of the source electrode 13 into the source trenches 11 is enhanced, whereby flatness of the source electrode 13 in the contact holes 12a is increased. In addition, the width of the contact holes 12a increases, whereby a slope of an edge (portion connecting a portion of the source electrode 13 on the interlayer insulating film 12 and portions in the contact holes 12a) of a step formed at the surface of the source electrode due to a height difference between the interlayer insulating film 12 and the front surface of the semiconductor substrate 30 becomes gradual. Thus, over the entire surface of the source electrode 13, the flatness of the source electrode 13 increases and bonding of the bonding wire to the surface of the source electrode 13 is facilitated. Further, during wire bonding, locally applied stress to the source electrode 13 may be suppressed.

An interval w21 between any adjacent two of the source trenches 11 disposed in any one of the non-operating regions 62, for example, is substantially a same as the interval w12 between any one of the source trenches 11 and an adjacent one of the gate trenches 7. Each of the non-operating regions 62 is formed by an adjacent two of the source trenches 11, whereby, as compared to an instance in which the source trenches 11 are provided each having a width that is a same as a total width of two of the source trenches 11 in the first direction X, mesa region (semiconductor portion between adjacent trenches) patterns may be made uniform at the surface of the active region 51 and thus, formation of the gate trenches 7 and the source trenches 11 is facilitated.

In any one of the non-operating regions 62, while three or more of the source trenches 11 may be adjacent to one another in the first direction X, the greater the number of the source trenches 11 is increased, the smaller the operating region of the MOSFET becomes. The greater the number of the gate trenches 7 per unit cell increases, the smaller is the effect of mitigating electric field near the bottoms of the gate trenches 7 by the p-type deep base portions 4 at the bottoms of the source trenches 11 and thus, the number of the gate trenches 7 disposed in any one of the unit cells 61 is at most about two more than the number of the source trenches 11 disposed in any one of the non-operating regions 62 and, preferably, may be about one more.

As described above, according to the second embodiment, effects similar to those of the first embodiment may be obtained. Further, according to the second embodiment, multiple unit cells are provided apart from one another, whereby embeddability of the source electrode into the source trenches is enhanced and the flatness of the source electrode is improved.

In the foregoing, the present invention is not limited to the embodiments above and various modifications within a range not departing from the spirit of the invention are possible. Further, in the embodiments, while a first conductivity type is assumed to be an n-type and a second conductivity type is assumed to be a p, the present invention is similarly implemented when the first conductivity type is a p-type and the second conductivity type is an n-type.

According to the invention described above, the number of gate trenches (first trenches) per unit cell may be increased without increasing the number of source trenches (second trenches), which constitute non-operating regions. As a result, the number of channels per unit cell may be increased and the current density of the drift current may be increased.

The silicon carbide semiconductor device according to the present invention is a trench-gate silicon carbide semiconductor device that has source trenches and is capable of reducing on-resistance.

As described, the silicon carbide semiconductor device according to the present invention is useful for power semiconductor devices used in power converting equipment, power source devices used in various industrial machines, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A silicon carbide semiconductor device, comprising:
a semiconductor substrate containing silicon carbide and having a first main surface and a second main surface opposite to each other;
a first semiconductor region of a first conductivity type provided in the semiconductor substrate;
a second semiconductor region of a second conductivity type, provided in the semiconductor substrate between the first main surface of the semiconductor substrate and the first semiconductor region;
a plurality of third semiconductor regions of the first conductivity type, selectively provided in the semiconductor substrate between the first main surface of the semiconductor substrate and the second semiconductor region;
a plurality of first trenches penetrating through the plurality of third semiconductor regions and the second semiconductor region in a depth direction and terminating in the first semiconductor region;
a plurality of gate electrodes provided in the plurality of first trenches, via a plurality of gate insulating films;
a plurality of second trenches penetrating through the plurality of third semiconductor regions in the depth direction and terminating in the second semiconductor region, at a depth at least equal to a depth of the plurality of first trenches, each of the plurality of second trenches being provided apart from the plurality of first trenches;
a first electrode provided at the first main surface of the semiconductor substrate, the first electrode being embedded in the plurality of second trenches, and in contact with the second semiconductor region and the plurality of third semiconductor regions at inner walls of the plurality of second trenches; and
a second electrode provided at the second main surface of the semiconductor substrate, wherein
the plurality of second trenches is provided at a predetermined first pitch in a direction parallel to the first main surface of the semiconductor substrate, and
the plurality of first trenches is disposed at a predetermined second pitch in the direction, each between adjacent two of the plurality of second trenches.

2. The silicon carbide semiconductor device according to claim 1, wherein the plurality of first trenches and the plurality of second trenches are so arranged that each of the plurality of second trenches has, respectively on two sides thereof,
one of the plurality of first trenches, provided separately from said each second trench, and
another one of the plurality of second trenches, provided separately from said each second trench.

3. The silicon carbide semiconductor device according to claim 1, wherein a total area of the plurality of first trenches is greater than a total area of the plurality of second trenches.

4. The silicon carbide semiconductor device according to claim 1, wherein a width of each of the plurality of first trenches is less than a width of each of the plurality of second trenches.

5. The silicon carbide semiconductor device according to claim 1, further comprising:
an active region in which the first electrode is disposed, the active region including:
a first region facing the first electrode in the depth direction, and
a second region facing the gate pad in the depth direction; and
a gate pad provided on the first main surface of the semiconductor substrate, the gate pad being electrically insulated from the first electrode by an interlayer insulating film and being electrically connected to the plurality of gate electrodes, wherein
the plurality of first trenches and the plurality of second trenches are disposed in a same layout in the first region and in the second region, and
an insulating layer is embedded in the plurality of second trenches in the second region.

6. The silicon carbide semiconductor device according to claim 1, further comprising:
an active region in which the first electrode is disposed;
a termination region surrounding a periphery of the active region in a plan view of the silicon carbide semiconductor device;
an intermediate region between the active region and the termination region; and
a gate runner provided, in the intermediate region, at the first main surface of the semiconductor substrate via an oxide film, the gate runner surrounding the periphery of the active region, the gate runner being connected to the plurality of gate electrodes, wherein
the plurality of first trenches and the plurality of second trenches are disposed in a same layout in the active region and in the intermediate region, and
an insulating layer is embedded in the plurality of second trenches, in the intermediate region.

7. A silicon carbide semiconductor device, comprising:
a semiconductor substrate containing silicon carbide and having a first main surface and a second main surface opposite to each other;
a first semiconductor region of a first conductivity type provided in the semiconductor substrate;
a second semiconductor region of a second conductivity type provided in the semiconductor substrate between the first main surface of the semiconductor substrate and the first semiconductor region;
a plurality of third semiconductor regions of the first conductivity type, selectively provided in the semiconductor substrate between the first main surface of the semiconductor substrate and the second semiconductor region;
a plurality of first trenches penetrating through the plurality of third semiconductor regions and the second semiconductor region in a depth direction and terminating in the first semiconductor region;
a plurality of gate electrodes provided in the plurality of first trenches, via a plurality of gate insulating films;
a plurality of second trenches penetrating through the plurality of third semiconductor regions in a depth direction and terminating in the second semiconductor region, at a depth at least equal to a depth of the plurality of first trenches, each of the plurality of second trenches being provided apart from the plurality of first trenches;
a first electrode provided at the first main surface of the semiconductor substrate, the first electrode being embedded in the plurality of second trenches, and in contact with the second semiconductor region and the plurality of third semiconductor regions at inner walls of the plurality of second trenches; and
a second electrode provided at the second main surface of the semiconductor substrate, wherein
a total number of first trenches of the plurality of first trenches is greater than a total number of second trenches of the plurality of second trenches.

8. The silicon carbide semiconductor device according to claim 7, wherein a total area of the plurality of first trenches is greater than a total area of the plurality of second trenches.

9. The silicon carbide semiconductor device according to claim 7, wherein a width of each of the plurality of first trenches is less than a width of each of the plurality of second trenches.

10. The silicon carbide semiconductor device according to claim 7, further comprising:
an active region in which the first electrode is disposed, the active region including:
a first region facing the first electrode in the depth direction, and
a second region facing the gate pad in the depth direction; and
a gate pad provided on the first main surface of the semiconductor substrate, the gate pad being electrically insulated from the first electrode by an interlayer insulating film and being electrically connected to the plurality of gate electrodes, wherein
the plurality of first trenches and the plurality of second trenches are disposed in a same layout in the first region and in the second region, and
an insulating layer is embedded in the plurality of second trenches in the second region.

11. The silicon carbide semiconductor device according to claim 7, further comprising:
an active region in which the first electrode is disposed;
a termination region surrounding a periphery of the active region in a plan view of the silicon carbide semiconductor device;
an intermediate region between the active region and the termination region; and
a gate runner provided, in the intermediate region, at the first main surface of the semiconductor substrate via an oxide film, the gate runner surrounding the periphery of the active region, the gate runner being connected to the plurality of gate electrodes, wherein
the plurality of first trenches and the plurality of second trenches are disposed in a same layout in the active region and in the intermediate region, and
an insulating layer is embedded in the plurality of second trenches, in the intermediate region.
